(19) United States
(12) Patent Application Publication
(10) Pub. No.: US 2002/0109978 A1
(43) Pub. Date: Aug. 15, 2002

(54) Rigid EMI/EMC shielding device for electronic instrument placed in a metallic or metallized casing having an aperture

(75) Inventor: Ludovic Henry, Toulouse (FR)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THALES, Paris (FR)

(21) Appl. No.: 09/983,300

(22) Filed: Oct. 24, 2001

(30) Foreign Application Priority Data
Oct. 24, 2000 (FR) 00 13637

(51) Int. Cl. H05K 9/00

(52) U.S. Cl. 361/818

(57) ABSTRACT

The disclosed shielding device can be applied especially to LCD screens (4). This device comprises a mesh screen (1) welded to a metal frame (2), itself fixed behind the aperture (5) of the casing. The mesh screen is tensioned on the frame and protected by a plastic film (8).

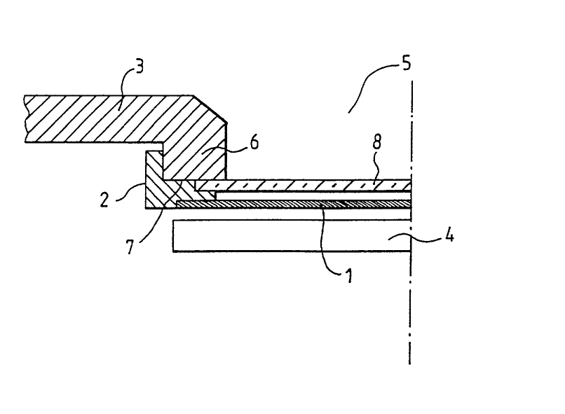

### BACKGROUND OF THE INVENTION

1. Field of the Invention

The present invention relates to a rigid EMI/EMC shielding device for an electronic instrument positioned in a metallic or metallized casing comprising an aperture.

Equipment having electronic circuits, whether it is commercial off-the-shelf equipment for large-scale consumption or equipment for professional or military purposes, has to be provided with electromagnetic shielding either to prevent its environment from being polluted if it is capable of emitting electromagnetic parasites (EMC or electromagnetic compatibility) or to avoid disturbance by the external parasites if it has elements sensitive to such parasites (EMI susceptibility).

Such equipment includes instruments comprising a display panel, which is the case with a large number of portable equipment or incorporated equipment (on board aircraft, land vehicles etc). While it is easy to shield an electronic instrument by enclosing it in a metal casing forming a Faraday cage, it is less easy to shield a display panel, such as an LCD panel, that forms a region through which electromagnetic waves have easy passage.

2. Description of the Prior Art

In a known way of shielding a display panel without optically masking it to an excessive degree, a fine mesh-screen made of metal is placed between two rigid transparent plates (made of polycarbonate or acrylic material) and the assembly (called a port) is placed in front of the display screen.

However, such an approach is far from satisfactory for the following three main reasons:

the assembly formed by the mesh screen and the port occupies a substantial amount of space owing to the considerable thickness of the port,

the metal wires must have a substantial diameter and a relatively small pitch to compensate for the very poor quality of the continuity of the shielding bordering the port, giving rise to a higher density of the meshes and hence to an increase in weight.

the reduction of the pitch of the meshes and the increase in the diameter of the wire that constitutes the meshes also leads to an increase in the luminosity of the screen, and this is especially inconvenient as the current trend is towards making highly luminous display panels known as “daylight” panels which can easily be seen in broad daylight.

### SUMMARY OF THE INVENTION

An object of the present invention is a device for the electromagnetic shielding of an electronic instrument that has a satisfactory shielding effect, brings about very little reduction in the luminosity of a display panel when it is in front of this display panel, and is neither bulky nor heavy.

The shielding device according to the invention, for a set of electronic instruments positioned in a metallic or metallized casing comprising an aperture, comprises a metal mesh screen fixed to a metal frame, this frame being fixed behind the aperture of the casing. Preferably, this fixing is done by welding. Advantageously, this mesh screen is tensioned when it is fixed to the frame. Also advantageously, the frame is stressed when it is being fixed to the screen.

### BRIEF DESCRIPTION OF THE DRAWING

The present invention will be understood more clearly from the following detailed description of an exemplary embodiment given by way of a non-restrictive example and illustrated by the appended drawing, wherein:

the single figure is a simplified view, in a partial section, of a touchpad display panel provided with a shielding according to the invention.

### MORE DETAILED DESCRIPTION

The invention is described here below with reference to a standard display panel (of the commercial off-the-shelf type for large-scale consumption) but it is clear that it can be applied to all types of civilian, industrial or military equipment placed in a metal box with an aperture (designed for example for the observation, from the outside, of an instrument placed in the box).

It is known that an operation to determine the pitch of the meshes of a shielding mesh screen is based on the following relationship which gives the shielding efficiency SE (in dB of attenuation of the electromagnetic waves) as a function of the pitch d of the meshes and the wavelength λ of these waves (if the diameter of the wire constituting the meshes is smaller than their pitch):

SE=20 log λ/2d

According to an exemplary embodiment of the invention, the mesh screen has rectangular meshes constituted by copper wires with a diameter of about 25 micrometers and a pitch of about 200 micrometers. However, it is clear that these parameters of the mesh screen may have other values depending on the efficiency sought, the wavelength of the parasite waves likely to appear throughout the period of use of the screen and the wires available.

As shown in the single figure, the metal mesh screen 1 is welded to a metal frame 2 whose shape and dimensions correspond to those of the aperture of the casing of the screen to be shielded. This frame has a height of some millimeters for example. The surface of the mesh screen 1 is greater than the surface of the aperture of the frame 2. This means that it is easy to weld the rim of the mesh screen 1 to the frame 2. This welding can be done in different ways, either by ultrasonic seam welding or by capacitor discharge welding or again by seam welding using a tin flux.

The frame 2 is fixed, for example by screwing, to the interior of the casing 3 enclosing the liquid crystal screen 4. The frame 2 is thus in direct electrical contact with the casing 3.

The screen 4 is positioned inside the casing 3 and can be seen through an aperture 5 formed in this casing. The casing 3 may be the original casing of the screen or an appropriate mechanical structure, for example the structure of an instrument in which this screen is placed. The edge 6 of the casing that borders the aperture 5 is pointed to the screen 4 and ends in a plane face 7 parallel to the screen 4 which is in a position that is withdrawn (by a few mm) with respect to this face 7.

In order to ensure perfect flatness and perfect tensioning for the mesh screen 1, it is stretched during the welding by means of an appropriate tool. To apply this tension, a mesh screen bigger than the frame is taken. Its edges are gripped by means of said tool and tension is applied to all the edges of the mesh screen with this tool. Naturally, after welding, the part of the mesh screen that goes beyond the frame is cut off.

To improve the tensioning of the mesh screen, the frame is stressed by a pressure applied to its sides and directed towards the exterior of the frame. After welding, the stress applied to the frame is released and the frame, by elasticity effect, stretches the mesh screen.

After the mesh screen has been welded to the frame, it is advantageously possible to blacken the mesh screen in order to prevent any parasitic reflections on the wires of the mesh screen.

According to an advantageous aspect of the invention, to protect not only the mesh screen but also the contents of the casing 3 from external mechanical and/or chemical attack, a protective film 8, for example of film made of plastic polymer, is fixed before the rear face of the mesh screen 1. This film is gripped between the face 7 of the edge 6 and the mesh screen 1.

Thus, through the device of the invention, a shielding is obtained with perfect electrical continuity between the metal mesh screen and a metal structure of the apparatus enclosing the screen, in accordance with the civilian and military EMC and EMI standards in force. This shielding device has minimum thickness, giving the casing 3 with a small thickness. Furthermore, the device has optimized transparency (possibly exceeding 75%) that only very slightly diminishes the luminosity of the screen.

The making of the frame/mesh-screen assembly described here above provides high-quality tensioning and flatness to the metal mesh screen, thus eliminating moire-type interference phenomena caused by its superimposition on the screen.

The space requirement of the device is the minimum (the edge 6 is shallow and the thickness of the frame 2 is also small).

Furthermore, the device of the invention, apart from its electromagnetic shielding function, offers possibilities of protection, especially against ultraviolet rays, chemical agents, impacts and scratches.

Naturally, contrast-improving filters can be added to the film 8.

What is claimed is:

1. A rigid EMI/EMC shielding device for an electronic instrument positioned in a metallic or metallized casing comprising an aperture, the shielding device comprising a metal mesh screen fixed to a metal frame, this frame being fixed behind the aperture of the casing.

2. A device according to claim 1, wherein the fixing of the mesh screen to the frame is done by welding.

3. A device according to claim 2, wherein the welding is one of the following types of welding: ultrasonic seam welding, capacitor discharge welding, seam welding using a tin flux.

4. A device according to one of the above claims, wherein the mesh screen is tensioned when it is fixed to the frame.

5. A device according to one of the above claims, wherein the mesh screen is stressed when it is fixed to the frame.

6. A device according to one of the above claims, comprising a plastic film (8) before the mesh screen.
